(19) United States
(12) Patent Application Publication
(10) Pub. No.: US 2008/0075135 A1
(43) Pub. Date: Mar. 27, 2008

(54) Laser diode

(75) Inventors: Wei Chang, San Chung City (TW); Huai-Fu Chen, San Chung City (TW); Chung-Nan Chen, San Chung City (TW)

Correspondence Address: TROXELL LAW OFFICE PLLC, SUITE 1404, 5205 LEESBURG PIKE, FALLS CHURCH, VA, 22041, US

(73) Assignee: Unity Opto Technology Co., Ltd.

(21) Appl. No.: 11/526,231

(22) Filed: Sep. 25, 2006

(51) Int. Cl. H01S 5/00

(52) U.S. Cl. 372/50.21

(57) ABSTRACT

A laser diode is disclosed. The laser diode generally has a support frame having a large-area coupling part and at least two pins on both ends, respectively, wherein one pin is integrally formed with the support frame. A laser diode chip and a photo-diode chip are attached to the large-area coupling part individually, and connected to other pins via two bonding wires, respectively. A transparent adhesive is formed on the photo-diode chip. The aforesaid components are integrated into a unity by a cover that has an opening on the top. Accordingly, the photo-diode chip can receive the laser light for utilizing the light feedback by an external circuit. Besides, the photo-diode chip and the laser diode chip are attached to the support frame directly so the laser diode offers good heat dissipation capability, extended lifetime, and increased reliability.

### FIELD OF THE INVENTION

The present invention relates to a laser diode able to offer good heat dissipation capability, extended lifetime, and increased reliability.

### BACKGROUND OF THE INVENTION

The laser diode has the advantages of high output power, rapid transmission speed, small lighting angle, and narrow spectrum (smaller chromatic dispersion) so it is more suitable for use in middle and long distance transmission. As shown in FIG. 5, a conventional laser diode generally comprises a base A on which two through holes, a recess region A1, and a pillar A2 are formed, wherein a pin B is coupled with a respective through hole. In addition, a pin A21 is extended from the bottom of the pillar A2. An adhesive is formed on the recess region A1, and a photo-diode chip C is attached onto the adhesive. The pillar A2 is then heat-melted at a temperature of 300 degrees centigrade so that a laser diode chip D can be attached to the pillar A2 to be perpendicular to the photo-diode chip C. Thereafter, these two chips are covered by a metal cover E that has a glasses window E1 on the top, and thus the conventional laser diode is completed.

The manufacture process of the aforesaid conventional laser diode is very minute and complicated. The photo-diode chip and the laser diode chip are attached at different positions by different attaching methods. The base must be laid flat first, and then rotated upside-down. Thus, the manufacture process is slowed down. Accordingly, there is disclosed another structure in which the laser diode chip is overlapped with the photo-diode chip directly. Therefore, its manufacture process is simplified and its production cost is reduced. However, the major drawback of this kind of conventional structure consists in its poorer heat dissipation capability.

In view of the foregoing description, the motive of the present invention is to provide the general public with a laser diode able to offer good heat dissipation capability, extended lifetime, and increased reliability.

### SUMMARY OF THE INVENTION

It is a main object of the present invention to provide a laser diode with good heat dissipation capability, extended lifetime, and increased reliability.

In order to achieve the above-mentioned object, a laser diode is disclosed. The laser diode has a support frame having a large-area coupling part on one end, and at least two pins are located on the other end. In addition, one pin is integrally formed with the support frame. A laser diode chip and a photo-diode chip are attached to the large-area coupling part individually, and connected to other pins via two bonding wires, respectively. A transparent adhesive is formed on the photo-diode chip. In addition, the aforesaid components are integrated into a unity by a cover that has an opening on the top. As a result, the photo-diode chip is able to receive the laser light for utilizing the light feedback by means of an external circuit. Besides, the photo-diode chip and the laser diode chip are attached to the support frame directly so the laser diode offers good heat dissipation capability, extended lifetime, and increased reliability.

The aforementioned objects and advantages of the present invention will be readily clarified in the description of the preferred embodiments and the enclosed drawings of the present invention.

### BRIEF DESCRIPTION OF THE DRAWINGS

FIG. 1 is an elevational diagram showing a preferred embodiment of the present invention.

FIG. 2 is an exploded diagram showing the preferred embodiment of the present invention.

FIG. 3 is a partial cross-sectional diagram showing the preferred embodiment of the present invention.

FIG. 4 is a partial cross-sectional diagram showing another preferred embodiment of the present invention.

FIG. 5 is a partial exploded diagram showing the conventional laser diode.

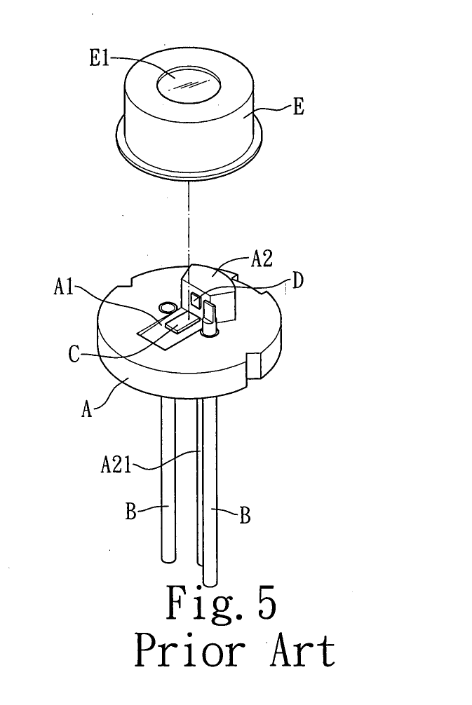

### DETAILED DESCRIPTION OF THE PREFERRED EMBODIMENT

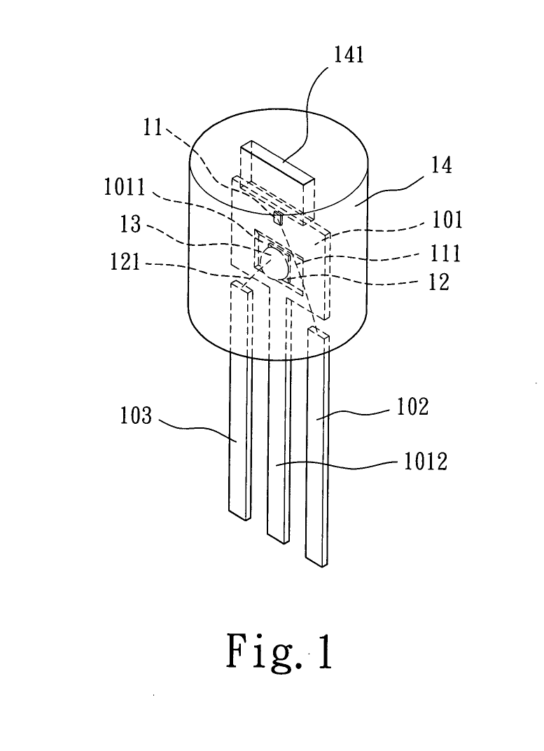

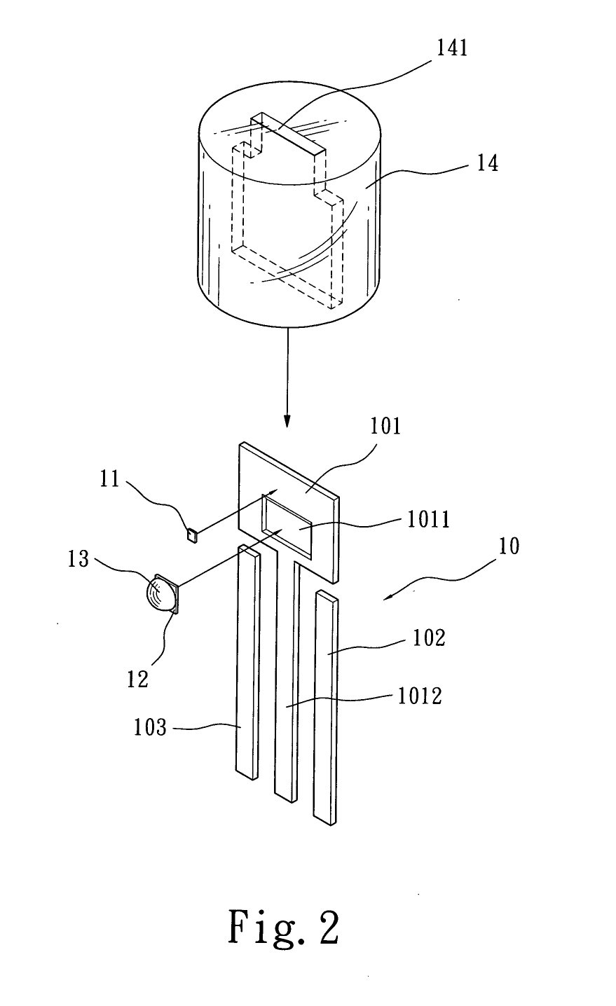

Referring to FIGS. 1 and 2 simultaneously, the present invention generally comprises a support frame 10, a laser diode chip 11, a photo-diode chip 12, a transparent adhesive 13, two bonding wires 111 and 121, and a cover 14. The support frame 10 has a large-area coupling part 101 on one end, wherein the large-area coupling part 101 has a recess region 1011 formed thereon. At least two pins, such as three pins 102, 103 and 1012 in this preferred embodiment, are located on the other end of the support frame 10. Besides, the middle pin 1012 is integrally formed with the large-area coupling part 101.

The laser diode chip 11 is attached to the large-area coupling part 101. The laser diode chip 11 is connected to the pin 102 via the bonding wire 111.

The photo-diode chip 12 is attached to the recess region 1011 of the large-area coupling part 101. Besides, the photo-diode chip 12 is connected to the pin 103 via the bonding wire 121. In addition, the transparent adhesive 13 is formed on the photo-diode chip 12 to form a convex lens. Moreover, the transparent adhesive 13 is also capable of protecting the bonding wire 121.

The cover 14 has an opening 141 on the top. The support frame 10, the laser diode chip 11, the photo-diode chip 12, the bonding wires 111 and 121, and the transparent adhesive 13 are integrated into the cover 14, and thus the assembly of the present invention is completed.

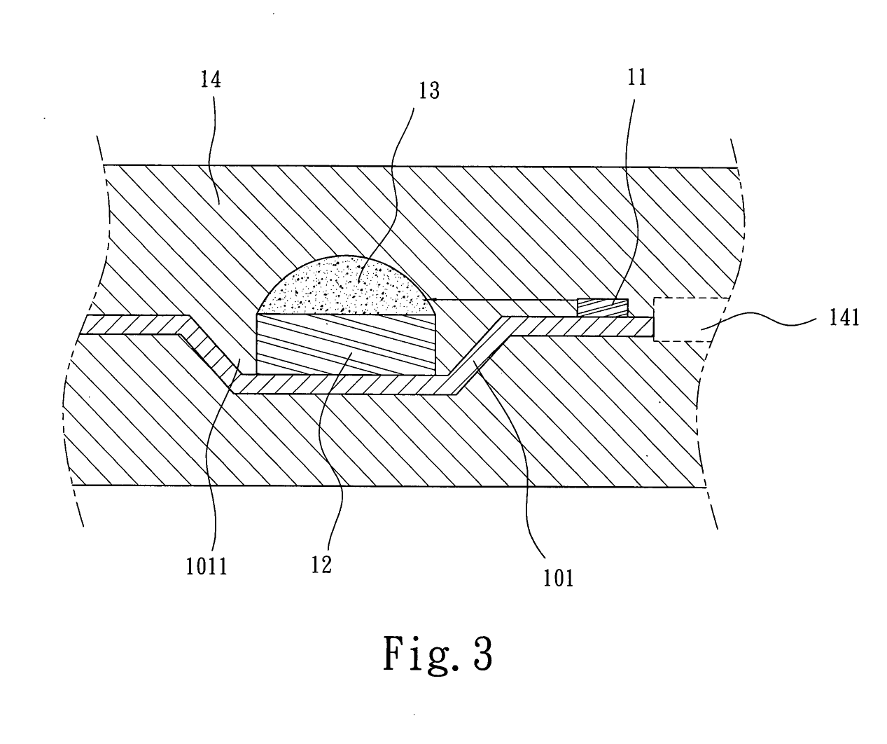

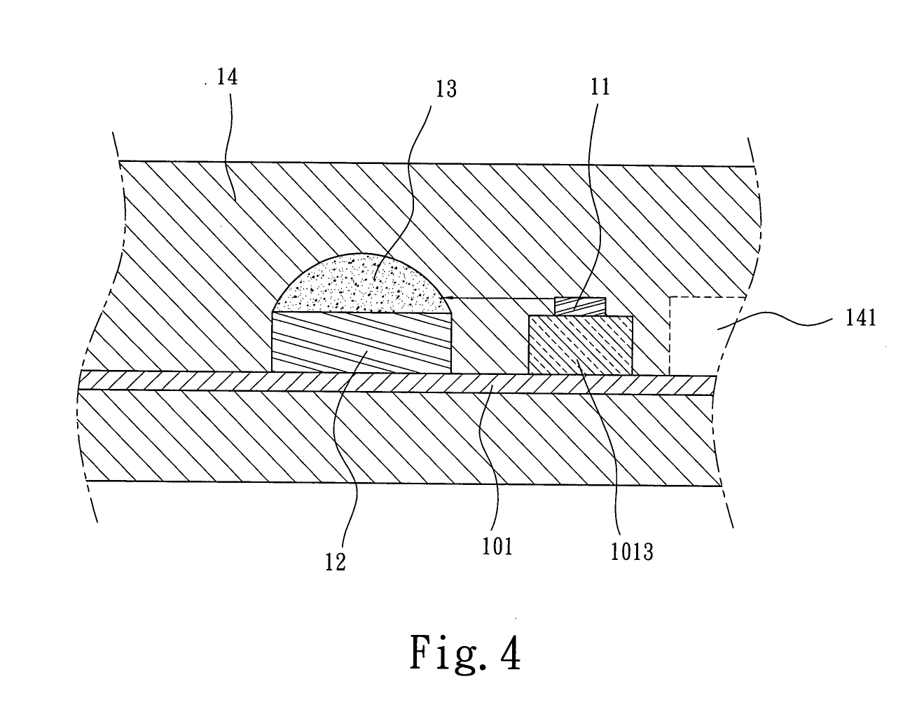

Furthermore, for the purpose of enabling the transparent adhesive 13 to absorb or reflect the laser light emitted from the backside of the laser diode chip 11 so as to allow the photo-diode chip 12 to utilize the light feedback, two solving ways are disclosed. In one solving way, as shown in FIG. 3, the recess region 1011 is formed on the large-area coupling part 101 of the support frame 10, and the laser diode chip 11 is attached to the large-area coupling part 101 outside of the recess region 1011 while the photo-diode chip 12 is attached to the inside of the recess region 1011, whereby the laser diode chip 11 is posited at a higher position than the photo-diode chip 12 to form a height difference between them so as to allow the transparent adhesive 13 on the top of the photo-diode chip 12 to be posited at a height corresponding to that of the laser diode chip 11. In the other solving way, as shown in FIG. 4, the photo-diode chip 12 is attached to the large-area coupling part 101 of the support frame 10 directly while the laser diode chip 11 is elevated by a spacer 1013 so as to allow the laser diode chip 11 to be posited at a height corresponding to that of the transparent adhesive 13. No matter which way is adopted, the opening 141 of the cover 14 is surely formed at a location corresponding to that of the laser diode chip 11.

In accordance with the foregoing description, the apparatus of the present invention has the following advantages:

1. The photo-diode chip and the laser diode chip are attached to the support frame directly so the laser diode has good heat dissipation capability and extended lifetime.

2. The transparent adhesive is formed on the photo-diode chip to form the convex lens on the light-collecting region of the photo-diode chip, thereby facilitating the reception of the light emitted from the backside of the laser diode chip for increasing the value of monitor current (Im).

3. The transparent adhesive formed on photo-diode chip is able to protect the bonding wire for promoting the reliability of the laser diode.

In summary, the present invention indeed achieves the anticipated objects by disclosing a laser diode able to offer good heat dissipation capability and extended lifetime. Accordingly, the present invention satisfies the requirement for patentability and is therefore submitted for a patent.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. A laser diode comprising:
a support frame having a large-area coupling part on one end and at least two pins located on the other end, one of said at least two pins being integrally formed with said support frame;
a laser diode chip and a photo-diode chip attached to said large-area coupling part individually, said laser diode chip and said photo-diode chip being connected to the other of said at least two pins via two bonding wires, respectively;
a transparent adhesive formed on said photo-diode chip at a height corresponding to that of said laser diode chip; and
a cover having an opening on the top for integrating aforesaid components into a unity.

2. The laser diode of claim 1, wherein said large-area coupling part of said support frame has a recess region formed thereon, said laser diode chip is attached to said large-area coupling part outside of said recess region, and said photo-diode chip is attached to said large-area coupling part inside said recess region so as to form a height difference between said laser diode chip and said photo-diode chip, thereby allowing said laser diode chip to directly face said transparent adhesive formed on said photo-diode chip.

3. The laser diode of claim 1, wherein said photo-diode chip is attached to said large-area coupling part of said support frame directly, and said laser diode chip is attached to said large-area coupling part via a spacer so as to form a height difference between said laser diode chip and said photo-diode chip, thereby allowing said laser diode chip to directly face said transparent adhesive formed on said photo-diode chip.

4. The laser diode of claim 1, wherein said opening is formed on the top of said cover at a location corresponding to that of said laser diode chip.
